(19) United States
(12) Patent Application Publication
(10) Pub. No.: US 2017/0213993 A1
(43) Pub. Date: Jul. 27, 2017

(54) OPTICAL DEVICE

(71) Applicant: PIONEER CORPORATION, Tokyo (JP)

(72) Inventor: Takashi CHUMAN, Kawasaki-shi, Kanagawa (JP)

(21) Appl. No.: 15/329,559

(22) PCT Filed: Jul. 29, 2014
(86) PCT No.: PCT/JP2014/069941

§ 371 Date: Jan. 26, 2017

(51) Int. Cl. H01L 51/52; H01L 51/00; H01L 51/56; H01L 51/44

(52) U.S. Cl. CPC H01L 51/5203; H01L 51/441; H01L 51/0097; H01L 51/448; H01L 51/5206; H01L 51/5221; H01L 51/5253; H01L 51/56; H01L 2251/558; H01L 2251/301; H01L 2251/5338

(57) ABSTRACT

The optical device (100) is, for example, a light emitting device or a photoelectric conversion device (for example, a solar battery), and includes a substrate (110), a conductive section (124), a first electrode (120), a functional layer (130), and a second electrode (140). The conductive section (124) is formed on a first surface (112) of the substrate (110). The first electrode (120) covers the first surface (112) of the substrate (110) and the conductive section (124). The second electrode (140) overlaps the first electrode (120). The functional layer (130) is located between the first electrode (120) and the second electrode (140). The conductive section (124) has a configuration in which a first layer (210) and a second layer (220) are laminated in this order. An upper surface of an end part (222) of the second layer (220) is inclined in a direction approaching the first surface (112).

### TECHNICAL FIELD

The present invention relates to an optical device.

### BACKGROUND ART

In recent years, optical elements such as light emitting elements or photoelectric conversion elements have been actively developed. Above all, as a light emitting element, development of an organic EL element is progressing. The organic EL element has a configuration in which an organic layer is interposed between a first electrode made of a transparent conductive material and a second electrode. The transparent conductive material has a higher resistance than that of metals, and thus an auxiliary wiring made of metal is frequently formed in the first electrode.

For example, Patent Document 1 discloses that, in a display using an organic EL element, an auxiliary electrode is formed on a substrate, and a transparent electrode of an organic EL element is further formed thereon. In Patent Document 1, the auxiliary electrode is formed by using Al, Mo, Cr, Ni, W, or an alloy thereof. Patent Document 1 discloses that by allowing a side surface of the auxiliary electrode to be inclined, light reflected at the side surface of the auxiliary electrode is radiated to the outside. Here, it is disclosed that the above effect can be achieved when an inclination angle of the side surface of the auxiliary electrode is 65° or more with respect to the substrate.

### RELATED DOCUMENT

### Patent Document

[Patent Document 1] Japanese Unexamined Patent Application Publication No. 2004-119216

### SUMMARY OF THE INVENTION

In a case where an electrode, such as a transparent electrode, is formed on a conductive section, such as an auxiliary electrode, the electrode may be formed discontinuously at a boundary between the conductive section and a substrate, causing the resistance of the electrode to increase.

An example of a problem to be solved of the present invention is to prevent an increase in the resistance of an electrode at a boundary between a conductive section and a substrate in a case where the electrode is formed on the conductive section.

According to claim 1 of the invention, there is provided an optical device including a substrate; a conductive section formed on a first surface of the substrate; a first electrode covering the first surface and the conductive section; a second electrode overlapping the first electrode; and a functional layer located between the first electrode and the second electrode, in which the conductive section has a configuration in which a first layer and a second layer are laminated in this order on the first surface, and in which an upper surface of an end part of the second layer is inclined in a direction approaching the first surface.

### BRIEF DESCRIPTION OF THE DRAWINGS

The above object, and other objects, features and advantages will become apparent from a preferred embodiment described below and the following accompanying drawings.

FIG. 1 is a sectional view illustrating a configuration of an optical device according to an embodiment.

FIGS. 2 are sectional views illustrating a manufacturing method of the optical device.

FIG. 3 is a plan view of an optical device according to an Example.

FIG. 4 is a plan view of the optical device according to the Example.

FIG. 5 is a plan view of the optical device according to the Example.

FIG. 6 is a diagram illustrating a state in which the optical device is curved.

### DESCRIPTION OF EMBODIMENTS

Hereinafter, an embodiment of the present invention will be described with reference to the drawings. The same constituent elements are given the same reference numerals throughout all the drawings, and description will not be repeated as appropriate.

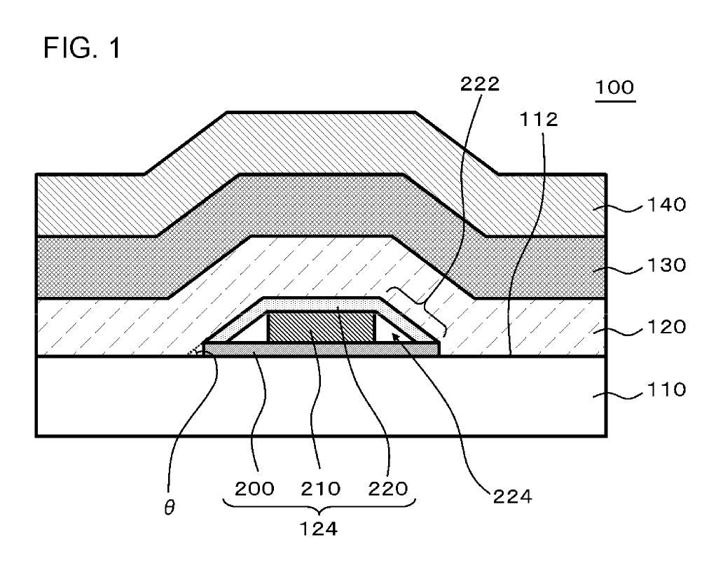

FIG. 1 is a sectional view illustrating a configuration of an optical device 100 according to the embodiment. The optical device 100 is, for example, a light emitting device or a photoelectric conversion device (for example, a solar battery), and includes a substrate 110, a conductive section 124, a first electrode 120, a functional layer 130, and a second electrode 140. The conductive section 124 is formed on a first surface 112 of the substrate 110. The first electrode 120 covers the first surface 112 of the substrate 110 and the conductive section 124. The second electrode 140 overlaps the first electrode 120. The functional layer 130 is located between the first electrode 120 and the second electrode 140. The conductive section 124 has a configuration in which a first layer 210 and a second layer 220 are laminated in this order. An upper surface of an end part 222 of the second layer 220 is inclined in a direction approaching the first surface 112. Hereinafter, details thereof will be described.

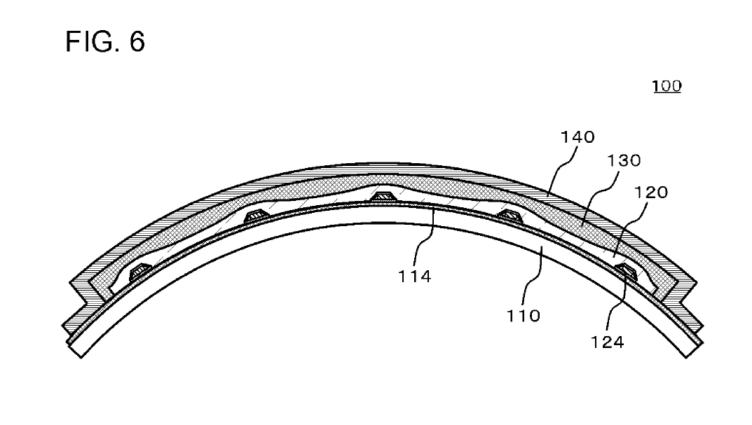

The substrate 110 is a transparent substrate such as a glass substrate or a resin substrate, and may be flexible as shown in an Example (FIG. 6) which will be described later. In a case where the substrate is flexible, a thickness of the substrate 110 is, for example, 10 μm or more and 1000 μm or less. The substrate 110 has a polygonal shape such as a rectangular shape. In a case where the substrate 110 is a resin substrate, the substrate 110 is formed by using, for example, polyethylene naphthalate (PEN), polyether sulfone (PES), polyethylene terephthalate (PET), or polyimide. In a case where the substrate 110 is a resin substrate, in order to prevent moisture from permeating through the substrate 110, an inorganic barrier film such as SiNₓ or SiON is formed on the first surface 112 of the substrate 110, or both of the first surface 112 and an opposite surface thereto.

An optical element is formed on the first surface 112 of the substrate 110. The optical element is a light emitting element or a photoelectric conversion element, and has a configuration in which the first electrode 120, the functional layer 130, and the second electrode 140 are laminated in this order.

The first electrode 120 is a light-transmissive transparent electrode. Materials of the transparent electrode are materials containing metal, for example, metal oxides such as an indium tin oxide (ITO), an indium zinc oxide (IZO), an indium tungsten zinc oxide (IWZO), and a zinc oxide (ZnO). A thickness of the first electrode 120 is, for example, 10 nm or more and 500 nm or less. The first electrode 120 is formed by, for example, sputtering or vapor deposition. The first electrode 120 may be formed of a carbon nanotube or may be made of a conductive organic material such as PEDOT/PSS.

The functional layer 130 is, for example, an organic layer or an inorganic layer and has a photoelectric conversion layer or a light emission layer. In a case where the optical device 100 is a light emitting device, the functional layer 130 has a configuration in which, for example, a hole injection layer, a light emission layer, and an electron injection layer are laminated in this order. A hole transport layer may be formed between the hole injection layer and the light emission layer. An electron transport layer may be formed between the light emission layer and the electron injection layer. The functional layer 130 may be formed by vapor deposition. At least one layer of the functional layer 130, a layer which is in contact with the first electrode 120 for example, may be formed by coating such as ink jet, printing, or spraying. In this case, the remaining layers of the functional layer 130 are formed by vapor deposition. All of the layers of the functional layer 130 may be formed by coating.

The second electrode 140 includes a metal layer made of a metal selected from a first group consisting of Al, Au, Ag, Pt, Mg, Sn, Zn, and In, or an alloy of metals selected from the first group, or a metal oxide such as an ITO or an IZO. A thickness of the second electrode 140 is, for example, 10 nm or more and 500 nm or less. The second electrode 140 is formed by, for example, sputtering or vapor deposition.

The conductive section 124 is formed between the first surface 112 and the first electrode 120. The conductive section 124 is, for example, an auxiliary electrode of the first electrode 120, and is in contact with the first electrode 120. The conductive section 124 has the first layer 210 and the second layer 220. In the example illustrated in FIG. 1, the conductive section 124 further has a third layer 200. The third layer 200 is located between the first layer 210 and the first surface 112. In other words, the conductive section 124 has a configuration in which the third layer 200, the first layer 210, and the second layer 220 are laminated in this order.

The first layer 210 is made of, for example, a metal such as Al or an Al alloy, and the second layer 220 and the third layer 200 are made of a conductive material having a higher hardness and a lower etching rate than those of the material of the first layer 210, for example, Mo or a Mo alloy. The first layer 210 is made of a material having lower resistance than that of a material of the third layer 200 and the second layer 220. In a case where the first layer 210 is made of an AlNd alloy, the second layer 220 and the third layer 200 are made of a MoNb alloy.

A thickness of the first layer 210 is, for example, 50 nm or more and 1000 nm or less and is preferably 100 nm or less. The second layer 220 is thinner than the first layer 210. A thickness of the second layer 220 is, for example, 30 nm or less, and is preferably 25 nm or less.

As described above, the upper surface of the end part 222 of the second layer 220 is inclined. Specifically, a width of the first layer 210 is smaller than a width of the second layer 220, and thus the first layer 210 is not located under the end part 222 of the second layer 220. The end part 222 of the second layer 220 is bent from a portion that overlaps with an end of the first layer 210. A width of the end part 222 (that is, a width of the bent portion) is, for example, 400 nm or more. An angle θ of the upper surface of the end part 222 with respect to the first surface 112 is, for example, 5° or more and 20° or less.

A void 224 is formed under the surface of the end part 222 on the first surface 112 side. Specifically, a width of the third layer 200 is larger than a width of the first layer 210, and thus the void 224 is located between the end part 222 and the third layer 200.

As described above, the first electrode 120 covers a part of the first surface 112 and the conductive section 124, and is bent at a boundary between the first surface 112 and the conductive section 124. Here, the upper surface of the end part of the conductive section 124, that is, the upper surface of the end part 222 of the second layer 220 is inclined in a direction approaching the first surface 112. Therefore, the bending angle of the first electrode 120 at the boundary between the first surface 112 and the conductive section 124 is reduced, and, as a result, the first electrode 120 is continuously formed at the boundary. Hereinafter, details thereof will be described.

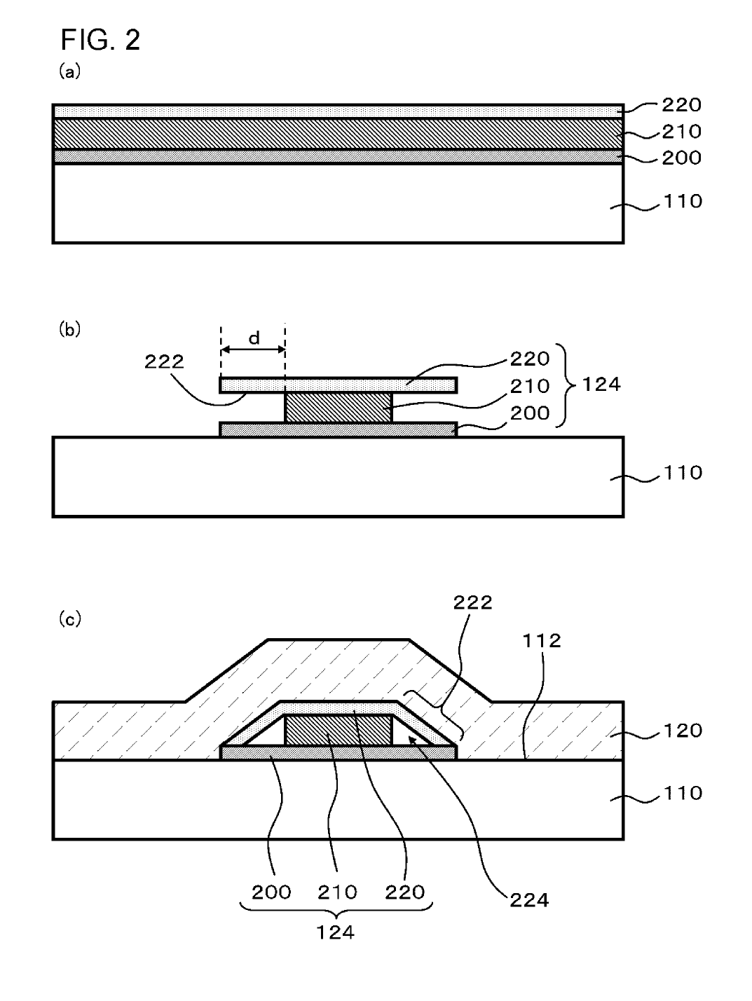

Respective drawings of FIGS. 2 are sectional views illustrating a manufacturing method of the optical device 100. First, as illustrated in FIG. 2(a), the third layer 200, the first layer 210, and the second layer 220 are formed on the substrate 110 in this order. The respective layers are formed by, for example, sputtering. In a case where the substrate 110 is a resin substrate, an inorganic barrier film such as SiNₓ or SiON is formed on the substrate 110 for moisture prevention, and the third layer 200 is formed on the inorganic barrier film (not illustrated).

Next, as illustrated in FIG. 2(b), a resist pattern (not illustrated) is formed on the second layer 220, and the second layer 220, the first layer 210, and the third layer 200 are etched (for example, wet-etched) by using the resist pattern as a mask. Consequently, the conductive section 124 is formed. Regarding a condition for this etching, an etching rate of the first layer 210 is higher than an etching rate of the third layer 200 and the second layer 220. Thus, the first layer 210 is etched faster than the third layer 200 and the second layer 220. As a result, a side surface of the first layer 210 comes closer toward the center of the conductive section 124 than side surfaces of the second layer 220 and the third layer 200, and thus the first layer 210 is not present under the end part of the second layer 220. Here, a distance d between the side surface of the first layer 210 and the side surface of the second layer 220 is preferably, for example, 400 nm or more. The length of the distance d is controlled by adjusting the etching condition (for example, etching time). At this stage, the end part 222 of the second layer 220 may be or may not be bent toward the first surface 112 of the substrate 110.

Next, as illustrated in FIG. 2(c), the first electrode 120 is formed on the substrate 110 and the conductive section 124 by, for example, sputtering. In a case where the end part 222 of the second layer 220 is not bent after the step illustrated in FIG. 2(b), the first electrode 120 is formed on the conductive section 124, and thus causing the end part 222 of the second layer 220 to bend toward the first surface 112 of the substrate 110. Since the bending angle of the first electrode 120 at the boundary between the first surface 112 and the conductive section 124 is small, the first electrode 120 is continuously formed at the boundary.

Thereafter, the functional layer 130 and the second electrode 140 are formed.

As mentioned above, according to the present embodiment, the upper surface of the end part 222 of the second layer 220 of the conductive section 124 is inclined toward the first surface 112 of the substrate 110. Consequently, the bending angle of the first electrode 120 at the boundary between the first surface 112 and the conductive section 124 is small. Therefore, the first electrode 120 is continuously formed at the boundary. As a result, it is possible to prevent an increase in the resistance of the first electrode 120 at the boundary between the conductive section 124 and the first surface 112. Particularly, in a case where the angle θ of the upper surface of the end part 222 with respect to the first surface 112 is 5° or more and 20° or less, the bending angle of the first electrode 120 at the boundary between the first surface 112 and the conductive section 124 is further reduced, and thus the resistance of the first electrode 120 at the boundary between the first surface 112 and the conductive section 124 is further prevented from increasing. Also in a case where the width of the end part 222 is 400 nm or more, the resistance of the first electrode 120 at the boundary between the first surface 112 and the conductive section 124 is further prevented from increasing for the same reason.

In the present embodiment, the etching rate of the first layer 210 is higher than the etching rate of the second layer 220. For this reason, the side surface of the first layer 210 is located further on the inside than the side surface of the second layer 220, and thus the end part 222 of the second layer 220 can be made to protrude outward of the first layer 210. In this case, the end part 222 is bent with the side surface (end) of the first layer 210 as a starting point, and thus the upper surface of the end part 222 can be easily inclined toward the first surface 112 of the substrate 110.

### EXAMPLE

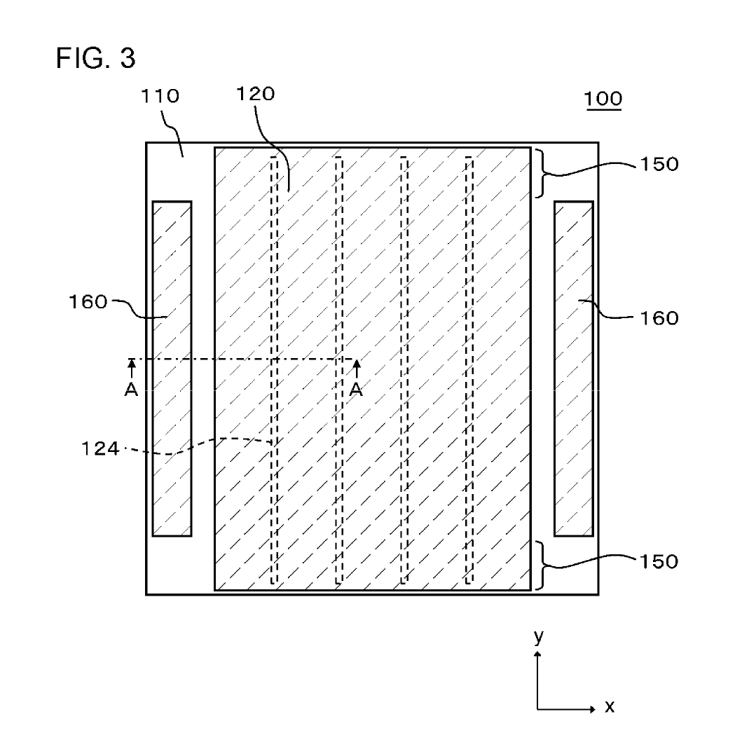

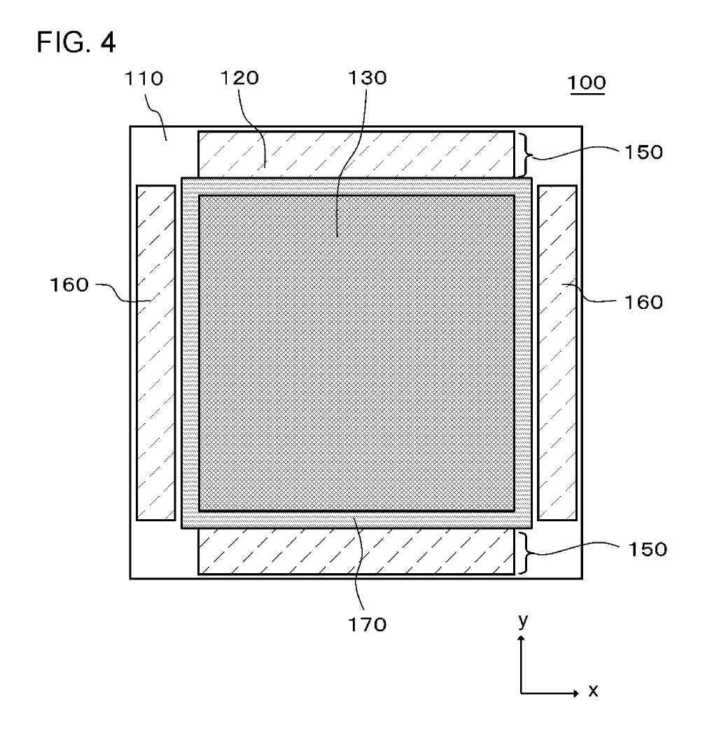

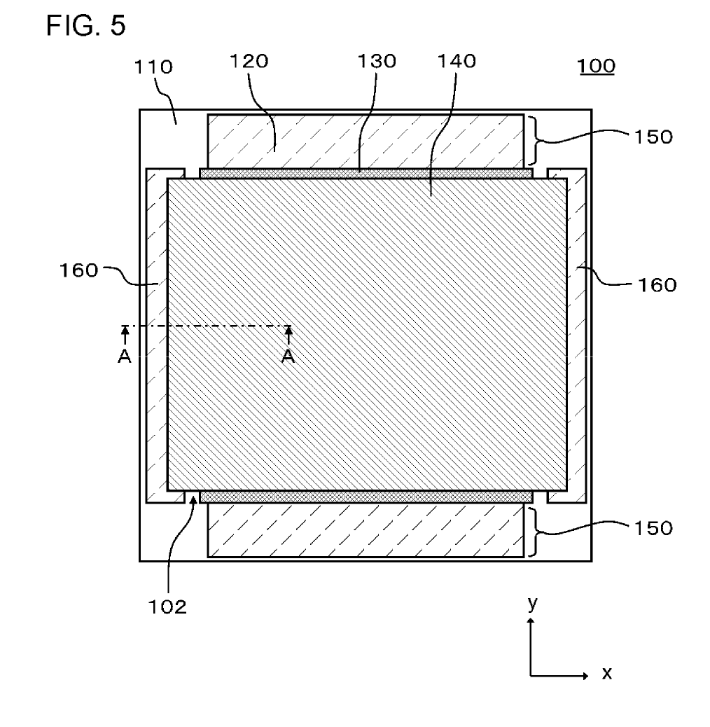

FIGS. 3, 4 and 5 are plan views of the optical device 100. FIG. 4 is a diagram in which the second electrode 140 is omitted from FIG. 5, and FIG. 3 is a diagram in which the functional layer 130 is omitted from FIG. 4. The optical device 100 illustrated in the figures is a light emitting device, and is used as a lighting device.

The optical device 100 has a polygonal shape such as a rectangular shape, and includes an organic EL element 102 (illustrated in FIG. 5), first terminals 150, and second terminals 160. A light emission region of the optical device 100 is formed by the organic EL element 102. A layout of each constituent element of the optical device 100 described below is only an example.

The organic EL element 102 has a configuration in which the first electrode 120, the functional layer 130, and the second electrode 140 are laminated on the substrate 110. Since the first electrode 120 is a transparent electrode, light emitted from the organic EL element 102 is emitted to the outside through the first electrode 120.

The first electrode 120 is an anode of the organic EL element 102, and is connected to the first terminals 150 as illustrated in FIG. 3. The first electrode 120 is continuously formed from a region serving as a light emission portion of the substrate 110 to the first terminals 150. In the example illustrated in this figure, the substrate 110 has a rectangular shape, and the first terminals 150 are provided along two sides opposing each other of the substrate 110. The first electrode 120 is formed between the two sides.

The functional layer 130 is formed on a part of the first electrode 120. A light emission region of the organic EL element 102 is defined by a region of the first electrode 120 in which the functional layer 130 is formed.

The region in which the functional layer 130 is formed is partitioned by an insulating layer 170. The insulating layer 170 is made of a photosensitive resin material such as polyimide, and surrounds the portion corresponding to a light emission region out of the first electrode 120. The functional layer 130 is formed in an inner region of the insulating layer 170. In other words, the functional layer 130 is formed in the region surrounded by the insulating layer 170.

The second electrode 140 functions as a cathode of the organic EL element 102. The second electrode 140 is formed on the functional layer 130, and is also connected to the second terminals 160. In the example illustrated in this figure, the second terminals 160 are formed along two sides of the substrate 110 opposing each other. The second electrode 140 is formed to cover a region between the two second terminals 160.

The first terminals 150 and the second terminals 160 are disposed on the outside of the organic EL element 102. Specifically, the two first terminals 150 are disposed separated from each other in a first direction, and the two second terminals 160 are disposed separated from each other in a second direction. The first terminals 150 and the second terminals 160 are provided to supply power to the organic EL element 102. The first terminals 150 and the second terminals 160 are connected to conductive members, for example, lead terminals or bonding wires.

The first terminals 150 are formed in the same layer as the first electrode 120 and are integral with the first electrode 120. Thus, a distance between the first terminal 150 and the first electrode 120 can be reduced, and thus a resistance value therebetween can be reduced. In addition, a non-light emission region present at edges of the optical device 100 can be narrowed.

The second terminals 160 are made of the same material as that of the first electrode 120. However, the second terminals 160 are separated from the first electrode 120.

The conductive section 124 is formed between the substrate 110 and the first electrode 120. The conductive section 124 is an auxiliary electrode of the first electrode 120 and is formed in a linear shape. In the example illustrated in this figure, a plurality of conductive sections 124 are formed to be parallel to each other. However, a plurality of conductive sections 124 may be formed in dotted shapes. A sectional structure and a forming method of the conductive section 124 are the same as those described in the embodiment.

The same layer as the conductive section 124 may be formed between the first terminal 150 and the substrate 110, and between the second terminal 160 and the substrate 110. In this case, the resistance of the first terminals 150 and the second terminals 160 can be reduced.

FIG. 6 is a diagram illustrating a state in which the optical device 100 is curved in a case where a flexible substrate is used as the substrate 110. In a case where the substrate 110 is a resin substrate, an inorganic barrier film 114 such as SiNₓ or SiON for moisture prevention is formed on the first surface 112 of the substrate 110 or both of the first surface 112 and an opposite surface thereto. The optical device 100 (that is, the substrate 110) is curved in a direction intersecting the conductive section 124, for example, in a direction (the x direction in FIG. 3) orthogonal to the conductive section 124. In a case where the substrate 110 is curved, force in the curved direction is applied to the laminate structure of the first electrode 120, the functional layer 130, and the second electrode 140. Here, if a region of the first electrode 120 located at the boundary between the substrate 110 and the conductive section 124 is discontinuously formed, a crack may occur in the first electrode 120 with the discontinuous portion as a starting point. In contrast, according to the present example, the region of the first electrode 120 located at the boundary between the substrate 110 and the conductive section 124 is continuously formed. Therefore, even if the optical device 100 is curved, it is possible to prevent the occurrence of a crack in the first electrode 120.

As mentioned above, although the embodiment and the Example have been described with reference to the drawings, these are only examples of the present invention, and various configurations other than the above-described configurations may be employed.

1. An optical device comprising:
a substrate;
a conductive section formed over a first surface of the substrate;
a first electrode covering the first surface and the conductive section;
a second electrode overlapping the first electrode; and
a functional layer located between the first electrode and the second electrode,
wherein the conductive section has a configuration in which a first layer and a second layer are laminated over the first surface in this order, and
an upper surface of an end part of the second layer is inclined in a direction approaching the first surface.

2. The optical device according to claim 1,
wherein a width of the first layer is smaller than a width of the second layer, and
wherein the end part of the second layer does not overlap the first layer and is bent toward the first surface.

3. The optical device according to claim 2,
wherein the end part of the second layer is bent from a portion that overlaps an end of the first layer as a starting point.

4. The optical device according to claim 3,
wherein a void is present under a surface of the end part of the second layer on the first surface side.

5. The optical device according to claim 4,
wherein the conductive section includes a third layer located between the first surface and the first layer, and
wherein the third layer is also formed at a location overlapped by the end part of the second layer, and the void is located between the end part of the second layer and the third layer.

6. The optical device according to claim 5,
wherein the substrate is flexible, and
wherein the optical device further includes a barrier film provided over the first surface of the substrate.

7. The optical device according to claim 6,
wherein an etching rate of the first layer is higher than an etching rate of the second layer.

8. The optical device according to claim 7,
wherein the first electrode is continuously formed from the first surface to over the conductive section.

9. The optical device according to claim 8,
wherein the conductive section is formed in a linear shape or a dotted shape.

10. The optical device according to claim 9,
wherein an angle formed between the end part of the second layer and the first surface is 5° or more and 20° or less.

11. The optical device according to claim 10,
wherein a width of the bent portion of the end part of the second layer is 400 nm or more.

12. The optical device according to claim 11,
wherein a thickness of the second layer is 30 nm or less.

13. The optical device according to claim 12,
wherein the first layer is made of Al or an Al alloy, and
wherein the second layer is made of Mo or a Mo alloy.

14. The optical device according to claim 13,
wherein the functional layer is an organic layer.
